(19) United States
(12) Patent Application Publication
(10) Pub. No.: US 2025/0024583 A1
(43) Pub. Date: Jan. 16, 2025

(54) ELECTRONIC SUBASSEMBLY WITH IMPROVED MOUNTING OF A HEAT SINK

(71) Applicant: Siemens Aktiengesellschaft, München (DE)

(72) Inventor: Peter Sturm, Hessdorf (DE)

(73) Assignee: Siemens Aktiengesellschaft, München (DE)

(21) Appl. No.: 18/767,407

(22) Filed: Jul. 9, 2024

(30) Foreign Application Priority Data
Jul. 10, 2023 (EP) 23184489.5

(51) Int. Cl. H05K 1/02

(52) U.S. Cl. CPC H05K 1/0203; H05K 1/0256; H05K 2201/10598

(57) ABSTRACT

An electronic subassembly includes an electronic unit arranged on a component side of a printed circuit board, a heat sink placed with a contact surface on a cooling surface of the electronic unit, a clip overlapping the heat sink and connected to the printed circuit board, and an auxiliary structure made of electrically insulating material and placed on the component side. The auxiliary structure includes a clip receiver in which the clip is introduced before placement of the auxiliary structure, and a heat sink receiver in which the heat sink is introduced before placement of the auxiliary structure and held and guided therein. The heat sink receiver includes retaining hooks to limit a movement of the heat sink in direction of the printed circuit board. The heat sink is spaced apart from the retaining hooks or pressed onto the retaining hooks by the clip while the auxiliary structure is bent.

### CROSS-REFERENCES TO RELATED APPLICATIONS

This application claims the priority of European Patent Application, Ser. No. 23/184,489.5, filed Jul. 10, 2023, pursuant to 35 U.S.C. 119 (a)-(d), the disclosure of which is incorporated herein by reference in its entirety as if fully set forth herein.

### BACKGROUND OF THE INVENTION

The invention relates to an electronic subassembly.

The following discussion of related art is provided to assist the reader in understanding the advantages of the invention, and is not to be construed as an admission that this related art is prior art to this invention.

Subassemblies of the kind involved here have a heat sink and a clip connected to a printed circuit board. Placement of the heat sink and the clip and the connection of the clip often take place manually. The heat sink and the clip are therefore successively placed on the heat sink by hand. Thereafter the clip is likewise manually connected to the printed circuit board. This approach has shortcomings because a cooling surface of an electronic unit on the subassembly is relatively small, particular when a contact surface of the heat sink is oriented at a certain angle relative to the cooling surface of the electronic unit and the contact surface of the heat sink is therefore tilted relative to the cooling surface of the unit. The thermal contact between the electronic unit and the heat sink consequently deteriorates, so that only poor cooling of the electronic unit is possible. The electronic unit is consequently only inadequately cooled. Inadequate cooling cannot be adequately improved by a heat-conducting paste introduced between the cooling surface and the contact surface either. As a consequence, the electronic unit can only be operated with reduced capacity (for example in the case of a processor, with only a reduced clock frequency) or damage to and failure of the electronic unit, and therewith of the electronic subassembly as a whole, occur relatively soon.

It would therefore be desirable and advantageous to provide an improved electronic subassembly to obviate prior art shortcomings.

### SUMMARY OF THE INVENTION

According to one aspect of the invention, an electronic subassembly includes a printed circuit board having a component side, an electronic unit arranged on the component side and having on a printed-circuit-board-remote side a cooling surface in parallel relation to the printed circuit board, a heat sink placed with a contact surface on the cooling surface of the electronic unit, a clip designed to overlap the heat sink at a side remote from the electronic unit and connected to the printed circuit board, and an auxiliary structure made of an electrically insulating material and placed on the component side of the printed circuit board, with the auxiliary structure including a clip receiver designed for introduction of the clip before placement of the auxiliary structure on the component side, and a heat sink receiver designed for introduction of the heat sink before placement of the auxiliary structure on the component side, with the heat sink being held and guided in the heat sink receiver, the heat sink receiver including retaining hooks designed to limit a movement of the heat sink in a direction of the printed circuit board, wherein after connection of the clip to the printed circuit board the heat sink is spaced apart from the retaining hooks or the heat sink is pressed onto the retaining hooks by the clip while the auxiliary structure is bent as the heat sink is pressed onto the retaining hooks by the clip.

The invention resolves prior art problems by realizing a parallel or at least substantially parallel orientation of the contact surface of the heat sink relative to the cooling surface of the electronic unit in a simple manner.

The electronic subassembly may involve a control subassembly (control unit) of an industrial control, for example a memory-programmable control or a numerical control or a motion control and may include a plurality of electronic units which are cooled by at least one heat sink. The electronic unit can be, for example, a processor.

The heat sink may have cooling ribs at a side remote from the contact surface of the heat sink. A heat-conducting component can be situated between the electronic unit and the heat sink, which component can be previously applied to the cooling surface or the contact surface. The heat-conducting component can be, for example, a heat-conducting paste or a plurality of small heat-conducting pads (PADs). The heat-conducting component can also include phase change materials (PCM).

The electronic unit may be soldered to the printed circuit board or may be inserted in a socket which in turn is soldered to the printed circuit board.

The clip can advantageously be connected to the printed circuit board by means of fixing screws.

The auxiliary structure can be made of a plastics material, such as a thermoplastic.

The clip receiver can be designed as required. For example, it is possible that the clip receiver makes contact with sections of the clip, which, when the auxiliary structure is placed on the component side, are oriented substantially orthogonally to the component side, at its sides facing each other and/or at its sides remote from each other.

When the heat sink is inserted in the heat sink receiver, substantially only a straight, linear movement of the heat sink is still possible. This also applies when the auxiliary structure has not yet been placed on the component side. The movement direction corresponds to the direction which, when the auxiliary structure is placed on the component side, is directed towards the printed circuit board.

A movement of the heat sink in a direction which, when the auxiliary structure is placed on the component side, is directed away from the circuit board, is possible to only a small extent. This movement, i.e. a movement away from the retaining hooks, is limited either by the clip or by elements of the auxiliary structure.

Contact is normally made between the contact surface of the heat sink and the cooling surface of the electronic unit when the auxiliary structure is placed on the component side. The heat sink is then lifted from the retaining hooks when the auxiliary structure is placed on the component side. From this instant, and thus also after connection of the clip to the printed circuit board, the heat sink is consequently spaced apart from the retaining hooks. A spacing of this kind of the heat sink from the retaining hooks is often very slight, usually 2 mm at most. As an alternative, it is possible for the auxiliary structure to have such a weak configuration that when the clip is connected to the printed circuit board the heat sink is lowered onto the retaining hooks again, in connection with the accompanying pressing-on of the heat sink onto the retaining hooks, but the auxiliary structure is bent.

According to another advantageous feature of the invention, the clip receiver can be designed in such a way that the clip is introducible into the clip receiver from a printed-circuit-board-facing side of the auxiliary structure (and only from this side), when the auxiliary structure is placed on the component side of the printed circuit board. This simplifies the construction of the auxiliary structure.

According to another advantageous feature of the invention, the clip, when introduced in the clip receiver, can be captively held in the auxiliary structure even before the heat sink is introduced into the heat sink receiver and before the auxiliary structure is placed on the component side of the printed circuit board. In this way, reliability is improved in terms of the production process of the electronic subassembly because when, for example, after introduction of the clip into the clip receiver, the auxiliary structure is transported from one mounting station to another mounting station, in which, for example, the heat sink is inserted in the heat sink receiver, the clip cannot get lost during this transportation.

According to another advantageous feature of the invention, the heat sink receiver can be designed in such a way that the heat sink is introduced into the heat sink receiver from a printed-circuit-board-facing side of the auxiliary structure (and only from this side), when the auxiliary structure is placed on the component side of the printed circuit board. This simplifies the construction of the auxiliary structure.

According to another advantageous feature of the invention, the auxiliary structure can include spacers designed to project in a direction away from the component side of the printed circuit board and to project over the heat sink in this direction. As a result, the auxiliary structure can easily be handled, when introducing the clip into the clip receiver and the heat sink into the heat sink receiver before placement of the auxiliary structure on the component side because it is possible to place the auxiliary structure on a flat base (for example the surface of a table), so that the auxiliary structure with the spacers stands up on the base (i.e. “reversed”). With this positioning and orientation of the auxiliary structure, the clip and the heat sink can then be successively introduced from above into the auxiliary structure. After introduction of the clip and the heat sink into the auxiliary structure the clip and the heat sink are pre-fixed in the auxiliary structure, so that the auxiliary structure, together with the clip and the heat sink, can be placed on the component side of the printed circuit board.

According to another advantageous feature of the invention, the auxiliary structure can include stops designed to limit a movement of the heat sink in a direction away from the printed circuit board. Pre-fixing of the heat sink inside the auxiliary structure can consequently be guaranteed, regardless of an exact positioning of the clip in the auxiliary structure and regardless of the configuration of the clip.

According to another advantageous feature of the invention, the retaining hooks and the stops can be positioned such as to match to the heat sink and to permit the heat sink to move by a maximum of 5 mm in the heat sink receiver. Reliability with which the contact surface of the heat sink is oriented parallel (or almost parallel) to the cooling surface of the electronic unit becomes greater, the less the heat sink can move in the heat sink receiver. Still, a certain minimum degree of movement is wanted in order to be able to compensate tolerances. Normally, it is sufficient when the heat sink can move in the heat sink receiver by less than 5 mm, for example by a maximum of 4 mm, a maximum of 3 mm or a maximum of 2 mm. Values below 2 mm are possible in many cases but are usually not necessary.

According to another advantageous feature of the invention, the heat sink in the heat sink receiver can be pressed onto the retaining hooks by the clip, when the clip is introduced in the clip receiver, before placement of the auxiliary structure on the component side of the printed circuit board. Defined positionings of the clip and of the heat sink in the auxiliary structure consequently are established before placement of the auxiliary structure on the component side.

According to another advantageous feature of the invention, the auxiliary structure can include positioning pins which are introduced into recesses of the printed circuit board. The positioning pins are introduced into the recesses when the auxiliary structure is placed on the component side. The positioning pins facilitate exact positioning of the auxiliary structure.

According to another advantageous feature of the invention, the auxiliary structure can include latching hooks for latching the auxiliary structure to the printed circuit board, with the latching hooks designed to overlap an outer side of the printed circuit board. This type of connection is particularly easy to implement.

### BRIEF DESCRIPTION OF THE DRAWING

Other features and advantages of the present invention will be more readily apparent upon reading the following description of currently preferred exemplified embodiments of the invention with reference to the accompanying drawing, in which:

FIG. 1 is a side view of parts of an electronic subassembly according to the invention;

FIG. 2 is a plan view from above of the parts of the electronic subassembly of FIG. 1;

FIG. 3 is a view from below of a heat sink and a clip;

FIG. 4 is a schematic illustration of an electronic subassembly as an auxiliary structure is placed on a component side of a printed circuit board;

FIG. 5 is a perspective illustration of an auxiliary structure;

FIG. 6 is a perspective illustration of the auxiliary structure of FIG. 5 with inserted clips;

FIG. 7 is a perspective illustration of the auxiliary structure of FIG. 5 with inserted clips and inserted heat sinks;

FIG. 8 is a front view of a clip;

FIG. 9 is a plan view from above of the clip of FIG. 8;

FIG. 10 is a side view of the clip of FIG. 8;

FIG. 11 is a partial illustration of a heat sink, a clip and an auxiliary structure;

FIG. 12 is a partial illustration of a heat sink, a clip and an auxiliary

structure;

FIG. 13 is a perspective illustration of an electronic subassembly; and structure.

FIG. 14 is a partial illustration of a heat sink, a clip and an auxiliary

### DETAILED DESCRIPTION OF PREFERRED EMBODIMENTS

Throughout all the figures, same or corresponding elements may generally be indicated by same reference numerals. These depicted embodiments are to be understood as illustrative of the invention and not as limiting in any way. It should also be understood that the figures are not necessarily to scale and that the embodiments may be illustrated by graphic symbols, phantom lines, diagrammatic illustrations and fragmentary views. In certain instances, details which are not necessary for an understanding of the present invention or which render other details difficult to perceive may have been omitted.

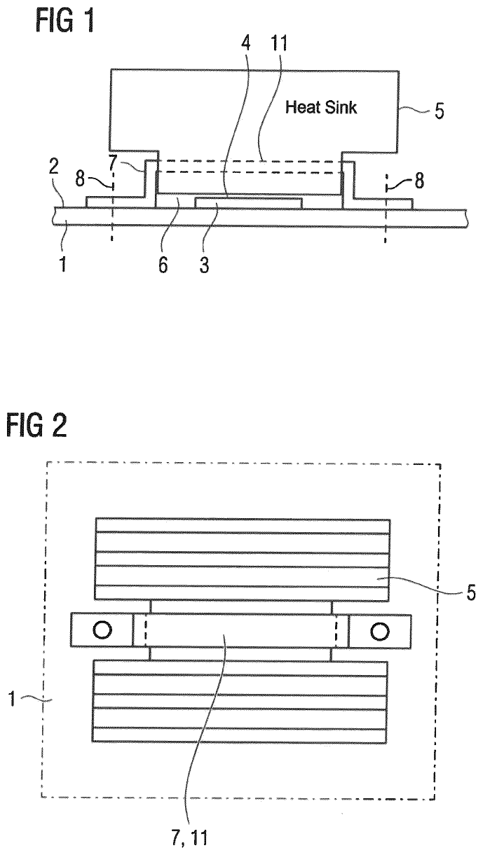

Turning now to the drawing, and in particular to FIGS. 1 and 2, there are shown an electronic subassembly which includes a printed circuit board 1. The printed circuit board 1 has a component side 2. An electronic unit 3 is arranged on the component side 2. Normally, a large number of electronic units 3 is arranged on the component side 2. For sake of simplicity, in the following description, reference is made to only the electronic unit designated by the reference character 3. The electronic unit 3 can be, for example, a processor. Independently of the type of electronic unit 3, on its side remote from the printed circuit board 1 the electronic unit 3 has a cooling surface 4. The cooling surface 4 runs parallel to the printed circuit board 1, i.e., parallel to the component side 2.

A heat sink 5 of the electronic subassembly is placed with a contact surface 6 on the cooling surface 4 of the electronic unit 3. The spacing of the contact surface 6 from the cooling surface 4 represented in FIG. 1 is not present in reality. A heat-conducting component (not shown) can be arranged between the cooling surface 4 and the contact surface 6. A clip 7 overlaps the heat sink 5 at a side which is remote from the electronic unit 3 (and also the printed circuit board 1). The clip 7 is connected to the printed circuit board 1, for example via schematically indicated connecting screws 8. Cooling ribs of the heat sink 5 are indicated in FIG. 2 though not labeled with a reference character.

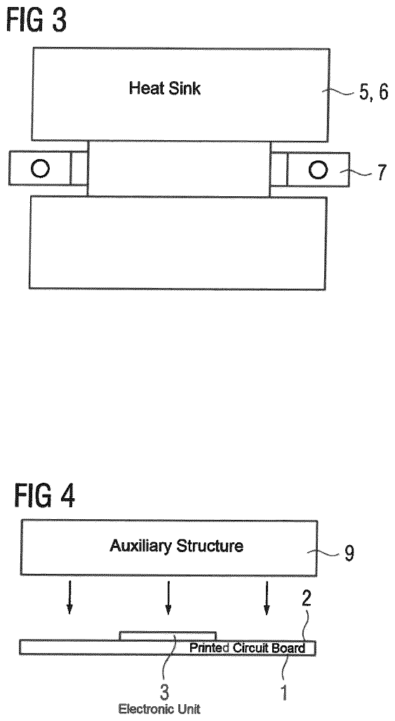

FIG. 3 shows, by way of example, a possible embodiment of the heat sink 5 and the associated cooperation with the clip 7, viewed from a lower side, i.e. viewed from the printed circuit board 1. In order to secure the heat sink 5 and the clip 7, the electronic subassembly in FIG. 4 has an auxiliary structure 9. The auxiliary structure 9 is made of an electrically insulating material. As indicated by arrows in FIG. 4, the auxiliary structure 9 is placed on the component side 2. Before placement on the component side 2, the heat sink 5 and the clip 7 are arranged in the auxiliary structure 9. After placement of the auxiliary structure 9 on the component side 2, the clip 7 is connected to the printed circuit board 1 and the contact surface 6 of the heat sink 5 is consequently pressed onto the cooling surface 4 of the electronic unit 3 by means of the clip 7.

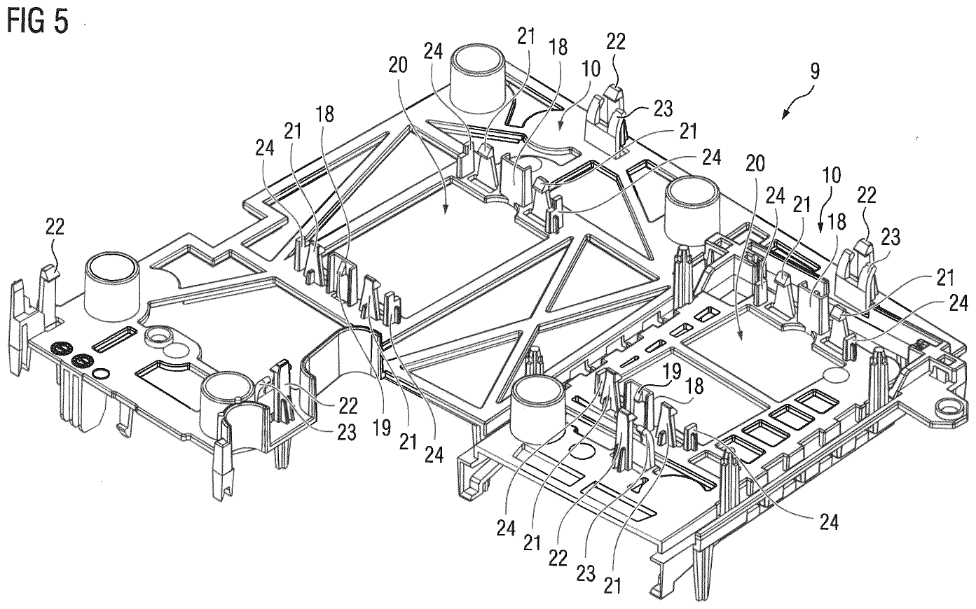

The structural design of the auxiliary structure 9 will be explained below firstly in connection with FIGS. 5 to 7. Equipping the auxiliary structure 9 with the heat sink 5 and the clip 7 will also be explained in connection with FIGS. 5 to 7.

From the subsequent explanations in relation to FIGS. 5 to 7, it will follow that the auxiliary structure 9 is configured for receiving two heat sinks 5 and two associated clips 7. The auxiliary structure 9 will be explained below in connection with this exemplified embodiment. It is also sufficient if the auxiliary structure 9 is configured for receiving only a single heat sink 5 and a single clip 7. Similarly, the auxiliary structure 9 could also be configured for receiving more than two heat sinks 5 and, corresponding herewith, more than two associated clips 7.

According to FIGS. 5 to 7, the auxiliary structure 9 includes a clip receiver 10 for each of the clips 7. The clip receivers 10 are matched to the clips 7. The clip receiver 10 for the respective clip 7 is matched to the clip 7 in such a way that the respective clip 7 can be introduced into the corresponding clip receiver 10 before placement of the auxiliary structure 9 on the component side 2 of the printed circuit board 1.

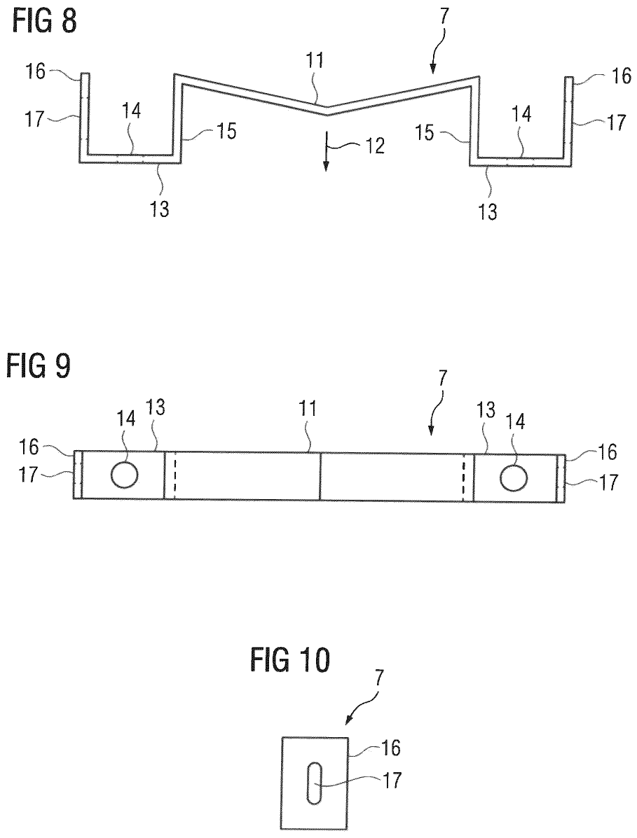

There is a plurality of possibilities for the configuration of the clips 7 and the clip receivers 10. In an exemplified configuration, the clips 7 according to FIGS. 8 to 10 are embodied, for example, in such a way that they have a pressure area 11 in a central region. According to FIGS. 1 and 2, in the mounted state (i.e. when the clip 7 is connected to the printed circuit board 1), the pressure area 11 is pressed onto the upper side of the heat sink 5. The pressure area 11 may advantageously be curved or angled, so that on lowering of the clip 7 in a direction designated by 12 in FIG. 8 firstly the central region of the pressure area 11 touches the heat sink 5 and thereafter the clip 7 is bent under the buildup of a compressive force.

Securing regions 13 adjoin both sides of the pressure area 11, with which regions the respective clip 7 is connected to the printed circuit board 1. For example, the securing regions 13 can have recesses 14 for passage of the connecting screws 8. The securing regions 13 are connected to the pressure area 11 via transitional sections 15. In the mounted state of the respective clip 7, the transitional sections 15 are oriented substantially orthogonally to the printed circuit board 1 while the pressure area 11 and the securing regions 13 run substantially parallel to the printed circuit board 1. End regions 16 adjoin the securing regions 13 on the outside. In the mounted state of the respective clip 7, the end regions 16 are likewise oriented substantially orthogonally to the printed circuit board 1. The end regions 16 can each have, for example, an oblong hole 17. In this case, the respective clip 7 can be mounted at its ends on the auxiliary structure 9 by means of two oblong holes 17.

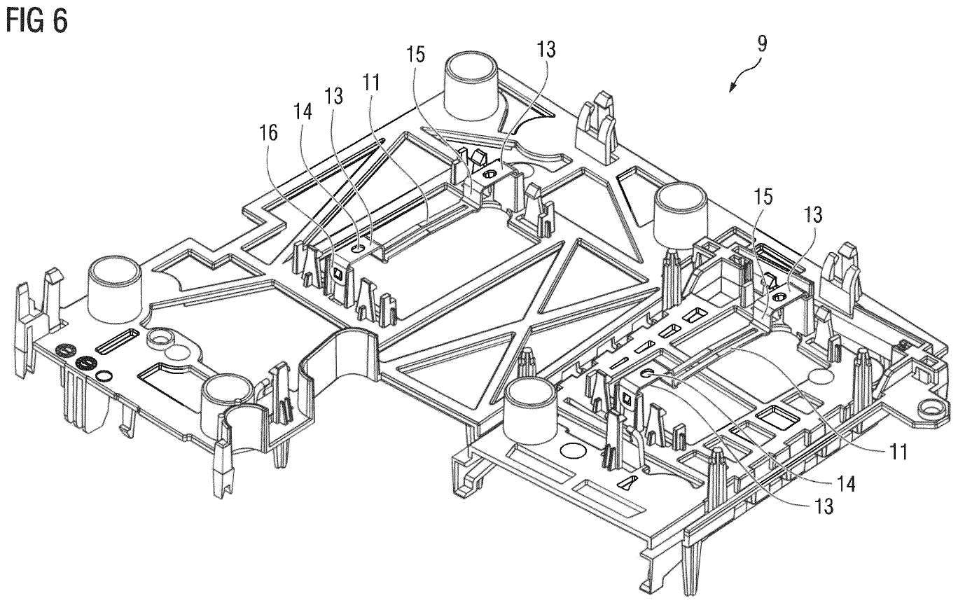

In the case of this exemplified configuration of the clips 7, the auxiliary structure 9 can have, for example, webs 18 as the clip receiver 10, the faces of which webs come to rest on the sides facing each other (alternatively: on the sides remote from each other) of the end regions 16 on insertion of the clip 7 in the clip receiver 10. In this case, the webs 18 can be embodied to be slightly resilient, for example, and at the corresponding faces have, for example, a projection 19 which is introduced into the corresponding slots on insertion of the respective clip 7 in the respective clip receiver 10. FIG. 6 shows the corresponding state of the auxiliary structure 9.

According to the illustration in FIG. 6, in the region of the respective pressure area 11, the clips 7 each have a longitudinal recess. This configuration of the clips 7 is advantageous but is less important in the context of the invention.

That side of the auxiliary structure 9, which subsequently (after placement of the auxiliary structure 9 on the component side 2) faces the component side 2, is arranged at the top in the illustration in FIGS. 5 to 7. The respective clip 7 is also introduced into the respective clip receiver 10 (in the illustration in FIGS. 5 to 7) from above. The respective clip 7 is thus inserted in the clip receiver 10 from that side of the auxiliary structure 9 which faces 9 the printed circuit board 1 when the auxiliary structure is placed on the component side 2. This involves an advantageous configuration.

Due to the projections 19, the respective clip 7 is, furthermore, captively held in the auxiliary structure 9 when it is in the respective clip receiver 10. This applies from the introduction of the respective clip 7 into the respective clip receiver 10 and therewith, in particular, also before the introduction of the respective heat sink 5 into a respective heat sink receiver 20 (will be explained below) and also before the placement of the auxiliary structure 9 on the component side 2.

According to FIGS. 5 to 7, the auxiliary structure 9 has, furthermore, for each of the heat sinks 5 the respective heat sink receiver 20 as has already been mentioned. The heat sink receivers 20 are matched to the heat sinks 5. The heat sink receiver 20 for the respective heat sink 5 is matched to the corresponding heat sink 5 in such a way that the heat sink 5 can be introduced into the corresponding heat sink receiver 20 before the placement of the auxiliary structure 9 on the component side 2 and the heat sink 5 is held and guided in the corresponding heat sink receiver 20.

The heat sink receivers 20 have—for example in the corner regions—retaining hooks 21. A movement of the respective heat sink 5 in the direction of the printed circuit board 1 is limited by the retaining hooks 21.

The respective heat sink 5 is thus also introduced into the respective heat sink receiver 20 from above in the illustration of FIGS. 5 to 7. The respective heat sink 5 is thus inserted into the respective heat sink receiver 20 from that side of the auxiliary structure 9 which faces the printed circuit board 1 when the auxiliary structure 9 is placed on the component side 2. This configuration requires, i.a., the respective heat sink 5 to be introduced into its heat sink receiver 20 only after the introduction of the associated clip 7 in the corresponding clip receiver 10.

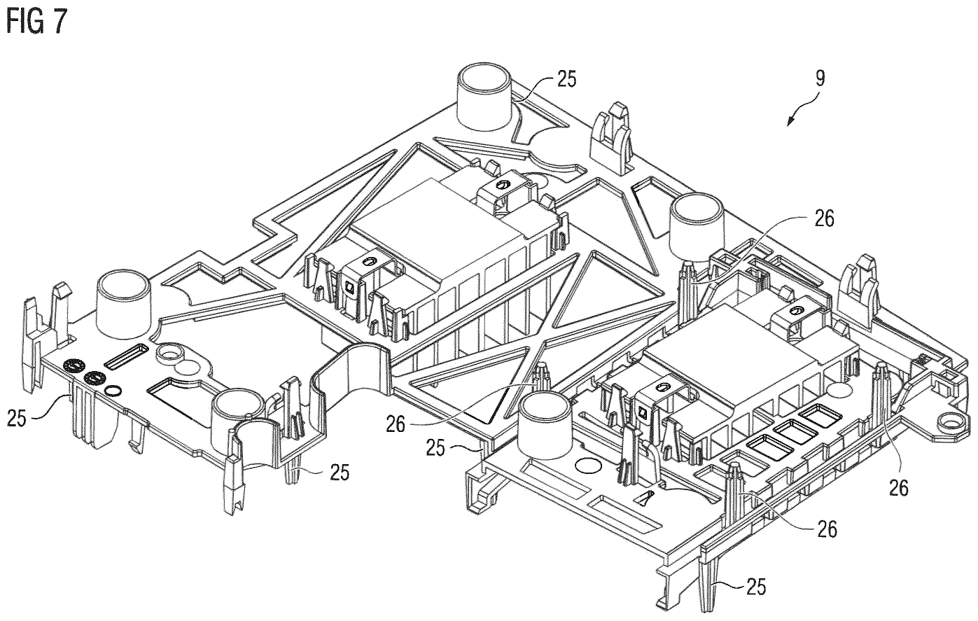

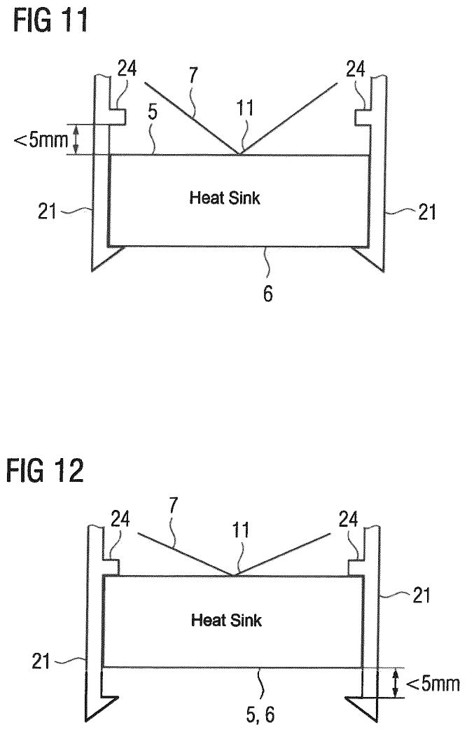

The afore-described configuration is advantageous. FIG. 7 shows the corresponding state of the auxiliary structure 9. In this state (i.e. in particular even before placement of the auxiliary structure 9 on the component side 2), the respective heat sink 5 is pressed onto the retaining hooks 21 by the respective clip 7. As already mentioned, the respective heat sink 5 is inserted in the corresponding heat sink receiver 20 in this connection and the respective clip 7 is also inserted in the respective clip receiver 10. FIG. 11 shows this state in a considerably simplified manner.

After introduction of the clips 7 into the clip receivers 10 and introduction of the heat sink 5 into the heat sink receivers 20, the auxiliary structure 9 is equipped. The auxiliary structure 9 can therefore now—cf. FIG. 4—be placed on the component side 2 of the printed circuit board 1. On placement, that side of the auxiliary structure 9, which is at the top in FIGS. 5 to 7, faces the component side 2. In order to secure the auxiliary structure 9 to the printed circuit board 1, the auxiliary structure 9 advantageously has latching hooks 22 according to FIGS. 5 to 7. The latching hooks 22 overlap the printed circuit board 1 at its outer side. The auxiliary structure 9, in cooperation with abutments 23 of the auxiliary structure 9, is latched to the printed circuit board 1 via the latching hooks 22.

During placement of the auxiliary structure 9 on the component side 2—i.e. even before placement of the auxiliary structure 9 on the component side 2 is concluded—the contact surface 6 of the respective heat sink 5 advantageously makes contact with the cooling surface 4 of the respective electronic unit 3. When the placement of the auxiliary structure 9 on the component side 2 is concluded, the respective heat sink 5 is therefore spaced apart from the retaining hooks 21 of the corresponding heat sink receiver 20. FIG. 12 shows the corresponding state. The cooling ribs of the heat sink 5 are not longitudinally oriented in the illustration of FIG. 12, instead they are transversely oriented. This is, however, less relevant in the context of the invention.

Advantageously, the auxiliary structure 9—see FIG. 11 again—has stops 24, by means of which the movement of the respective heat sink 5 is limited—i.e. the retreating of the respective heat sink 5 in the respective heat sink receiver 20 in the direction away from the printed circuit board 1. Positioning of the retaining hooks 21 and the stops 24 can advantageously be matched to the respective heat sink 5 in such a way that the respective heat sink 5 can move in the corresponding heat sink receiver 20 by a maximum of 5 mm.

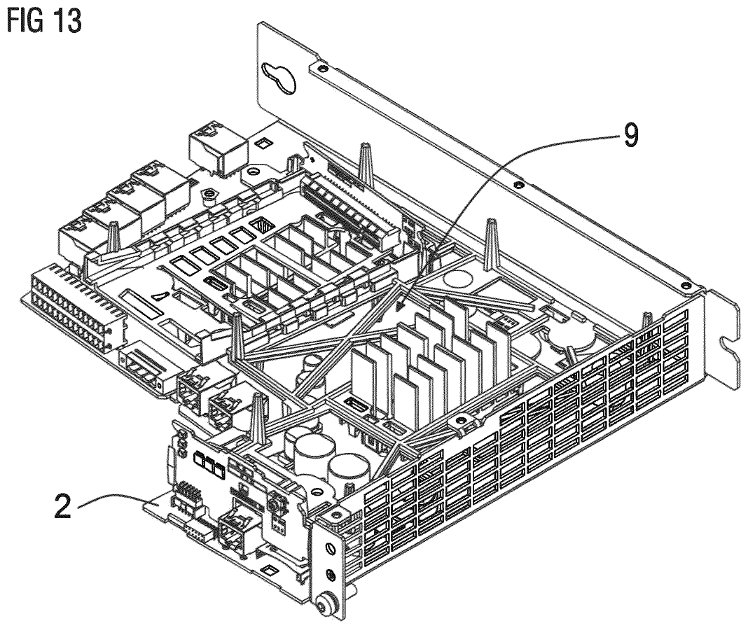

The stops 24 are represented in FIGS. 11 and 13 as component parts of the retaining hooks 21. This configuration, while possible, is generally not preferred, as opposed to the configuration shown in FIGS. 5 to 7, in which the stop 24 are independent elements, which are arranged next to the retaining hooks 21.

On subsequent connection of the clips 7 to the printed circuit board 1, the heat sinks 5 are usually lowered slightly onto the printed circuit board 1 again. FIG. 13 shows the electronic subassembly after the placement of the auxiliary structure 9 on the component side 2.

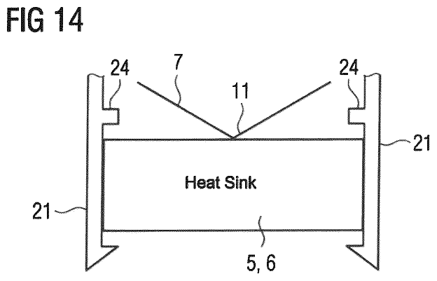

Usually the respective heat sink 5 is situated between the two extreme positions represented in FIGS. 11 and 12 after connection of the clips 7 to the printed circuit board 1, inside the respective heat sink receiver 20, corresponding to the illustration in FIG. 14. Advantageously, the respective heat sink 5 is therefore also spaced apart from the retaining hooks 21 after connection of the respective clip 7 to the printed circuit board 1.

As an alternative, it is possible for the respective heat sink 5 to be pressed onto the retaining hooks 21 again by means of the respective clip 7. In this case, the retaining hooks 21 should not impede the pressing of the respective heat sink 5 onto the associated electronic unit, however. The auxiliary structure 9 should therefore be designed to be so yielding such that the auxiliary structure 9 is bent by the pressing of the respective heat sink 5 onto the retaining hooks 21, i.e. the auxiliary structure 9 yields.

For simple equipping of the auxiliary structure 9, the auxiliary structure 9 according to FIGS. 5 to 7 advantageously has spacers 25. In the mounted state, the spacers 25 project away from the component side 2 of the printed circuit board 1. The spacers 25 are normally arranged at least in the region of the corners of the auxiliary structure 9. Furthermore, the spacers 25 project in this direction—i.e. away from the component side 2 of the printed circuit board 1—over the heat sink 5 (or in the case of a plurality of heat sinks 5, the heat sinks 5). It is consequently possible to place the auxiliary structure 9, as illustrated in FIGS. 5 to 7, with the spacers 25 on the surface of a table or the like and then to equip it problem-free with the clips 7 and the heat sinks 5.

For easy positioning of the auxiliary structure 9 on placement on the component side 2, the auxiliary structure 9 according to FIGS. 5 to 7 can, furthermore, have positioning pins 26. The positioning pins 26 are introduced in this case into corresponding recesses of the printed circuit board 1 (not shown). It is consequently guaranteed that the lateral positioning of the auxiliary structure 9 relative to the printed circuit board 1 is correct.

To summarize, the invention thus relates to the following facts:

An electronic subassembly has a printed circuit board 1 with a component side 2. Arranged on the component side 2 is an electronic unit 3 which on its side remote from the printed circuit board 1 has a cooling surface 4 running parallel to the printed circuit board 1. The electronic subassembly has a heat sink 5 which is placed with a contact surface 6 on the cooling surface 4 of the electronic unit 3. The electronic subassembly has a clip 7 which overlaps the heat sink 5 at its side remote from the unit 3 and is connected to the printed circuit board 1. The electronic subassembly has an auxiliary structure 9 which is made of an electrically insulating material and is placed on the component side 2. The auxiliary structure 9 has a clip receiver 10 for the clip 7 into which the clip 7 can be introduced before placement of the auxiliary structure 9 on the component side 2. The auxiliary structure 9 has a heat sink receiver 20 into which the heat sink 5 can be introduced before placement of the auxiliary structure 9 on the component side 2 and in which the heat sink 5 is held and guided. The heat sink receiver 20 has retaining hooks 21, by means of which a movement of the heat sink 5 is limited in the direction of the printed circuit board 1. After connection of the clip 7 to the printed circuit board 1 either the heat sink 5 is spaced apart from the retaining hooks 21 or the heat sink 5 is pressed onto the retaining hooks 21 by means of the clip 7 and the auxiliary structure 9 is bent by this pressing-on.

The invention has many advantages. Considerably simpler and more reliable mounting of the heat sink 5 on the electronic unit 3 are realized. Dissipation of heat is reliable. In particular, considerably better orientation of the contact surface 6 relative to the cooling surface 4 is achieved by the spacings of the retaining hooks 21 and the stops 24 which, viewed in the plane defined by the printed circuit board 1, significantly exceed the dimensions of the cooling surface 4 and the contact surface 6. The heat sink receivers 20 also hold the heat sinks 5 in their position on tightening of the connecting screws 8 and completely prevent, or at least almost completely prevent, tilting of the heat sink 5. Mounting can even be automated.

While the invention has been illustrated and described in connection with currently preferred embodiments shown and described in detail, it is not intended to be limited to the details shown since various modifications and structural changes may be made without departing in any way from the spirit and scope of the present invention. The embodiments were chosen and described in order to explain the principles of the invention and practical application to thereby enable a person skilled in the art to best utilize the invention and various embodiments with various modifications as are suited to the particular use contemplated.

What is claimed as new and desired to be protected by Letters Patent is set forth in the appended claims and includes equivalents of the elements recited therein:

What is claimed is:

1. An electronic subassembly, comprising:
a printed circuit board having a component side;
an electronic unit arranged on the component side and having on a printed-circuit-board-remote side a cooling surface in parallel relation to the printed circuit board;
a heat sink placed with a contact surface on the cooling surface of the electronic unit;
a clip designed to overlap the heat sink at a side remote from the electronic unit and connected to the printed circuit board; and
an auxiliary structure made of an electrically insulating material and placed on the component side of the printed circuit board, said auxiliary structure including a clip receiver designed for introduction of the clip before placement of the auxiliary structure on the component side, and a heat sink receiver designed for introduction of the heat sink before placement of the auxiliary structure on the component side, with the heat sink being held and guided in the heat sink receiver, said heat sink receiver including retaining hooks designed to limit a movement of the heat sink in a direction of the printed circuit board,
wherein after connection of the clip to the printed circuit board the heat sink is spaced apart from the retaining hooks or the heat sink is pressed onto the retaining hooks by the clip while the auxiliary structure is bent as the heat sink is pressed onto the retaining hooks by the clip.

2. The electronic subassembly of claim 1, wherein the clip receiver is designed in such a way that the clip is introducible into the clip receiver from a printed-circuit-board-facing side of the auxiliary structure when the auxiliary structure is placed on the component side of the printed circuit board.

3. The electronic subassembly of claim 1, wherein the clip, when introduced in the clip receiver, is captively held in the auxiliary structure even before the heat sink is introduced into the heat sink receiver and before the auxiliary structure is placed on the component side of the printed circuit board.

4. The electronic subassembly of claim 1, wherein the heat sink receiver is designed in such a way that the heat sink is introduced into the heat sink receiver from a printed-circuit-board-facing side of the auxiliary structure when the auxiliary structure is placed on the component side of the printed circuit board.

5. The electronic subassembly of claim 1, wherein the auxiliary structure includes spacers designed to project in a direction away from the component side of the printed circuit board and to project over the heat sink in said direction.

6. The electronic subassembly of claim 1, wherein the auxiliary structure includes stops designed to limit a movement of the heat sink in a direction away from the printed circuit board.

7. The electronic subassembly of claim 6, wherein the retaining hooks and the stops are positioned such as to match to the heat sink and to permit the heat sink to move by a maximum of 5 mm in the heat sink receiver.

8. The electronic subassembly of claim 1, wherein the heat sink in the heat sink receiver is pressed onto the retaining hooks by the clip, when the clip is introduced in the clip receiver, before placement of the auxiliary structure on the component side of the printed circuit board.

9. The electronic subassembly of claim 1, wherein the auxiliary structure includes positioning pins which are introduced into recesses of the printed circuit board.

10. The electronic subassembly of claim 1, wherein the auxiliary structure includes latching hooks for latching the auxiliary structure to the printed circuit board, said latching hooks designed to overlap an outer side of the printed circuit board.
